(19) United States
(12) Patent Application Publication
(10) Pub. No.: US 2025/0349510 A1
(43) Pub. Date: Nov. 13, 2025

(54) PLASMA ETCHING DEVICE AND METHOD OF OPERATION THEREOF

(71) Applicant: Samsung Display Co., Ltd., Yongin-Si (KR)

(72) Inventors: SOO BEOM JO, Yongin-si (KR); Myung Soo HUH, Yongin-si (KR); Cheol Lae ROH, Yongin-si (KR)

(21) Appl. No.: 19/007,245

(22) Filed: Dec. 31, 2024

(30) Foreign Application Priority Data
May 9, 2024 (KR) 10-2024-0061371

(51) Int. Cl. H01J 37/32

(52) U.S. Cl. CPC H01J 37/3211; H01J 37/32495; H01J 37/32862; H01J 2237/334

(57) ABSTRACT

The present disclosure relates to a plasma etching device, an embodiment of which includes: a chamber in which an etching process using plasma is performed, an inside of which is coated with an insulating layer before the etching process, the insulating layer being removable after the etching process; a first antenna connected to a high-frequency power source and positioned on the chamber; a second antenna connected to a low-frequency power source and positioned along at least a portion of a perimeter of the first antenna; and a controller electrically connected to control the high-frequency power source and the low-frequency power source.

### CROSS-REFERENCE TO RELATED APPLICATION

This application claims priority to and the benefit of Korean Patent Application No. 10-2024-0061371, filed at the Korean Intellectual Property Office on May 9, 2024, the entire contents of which are incorporated herein by reference.

### BACKGROUND

### Field

The present disclosure relates to a plasma etching device and an operating method thereof.

### Description of the Related Art

A display device in use today may be a flat panel display such as a liquid crystal display (LCD), a plasma display panel (PDP), an organic light emitting diode device (OLED device), a field emission display (FED), and an electrophoretic display device. Such a display device may include a plurality of layers, such as a light emitting layer and a plurality of layers forming signal lines and transistors, and a stack of layers containing signal lines may include a metal layer that is etched to form the signal lines. Copper, which has low resistance, is typically used as the metal layer, but some reaction by-products of copper etching have low volatility, which may cause re-adsorption of the by-products inside a chamber of an etching device. In this case, if a further etching process is performed after the by-products were adsorbed inside the chamber, activated ions in a plasma state may react with the by-products adsorbed inside the chamber, causing the by-products to fall inside the chamber, making the etching process unstable or subject to creating defects. Accordingly, the interior of the chamber must be periodically cleaned to remove etching by-products before performing further etching processes.

### SUMMARY

Embodiments disclosed herein may provide an apparatus and method for removing unwanted by-products in a chamber of a processing device.

An embodiment in accordance with the present disclosure may provide a plasma etching device including a chamber in which an etching process using plasma is performed. An inside of the chamber may be coated with an insulating layer before the etching process, and the insulating layer may be removed after the etching process. The etching device may further include a first antenna connected to a high-frequency power source and positioned on the chamber; a second antenna connected to a low-frequency power source and positioned along at least a portion of a circumference or perimeter of the first antenna; and a controller electrically connected to the high-frequency power source and the low-frequency power source to control the high-frequency power source and the low-frequency power source.

An embodiment in accordance with the present disclosure may provide an operating method for a plasma etching device including a chamber where an etching process using plasma is performed, a first antenna connected to a high-frequency power source and positioned on the chamber, a second antenna connected to a low-frequency power source and positioned at an outer edge of the first antenna; and a controller electrically connected to the high-frequency power source and the low-frequency power source, The operating method may include: coating an inside of the chamber with an insulating layer by applying low-frequency power to the second antenna; etching a target object to be etched by applying high-frequency power to the first antenna; and cleaning the inside of the chamber and removing the insulating layer by applying low-frequency power to the second antenna.

According to the embodiments, a facility operation rate for an etching chamber may be improved, and the number of manufactured devices rejected due to defects may be minimized by effectively removing reaction by-products inside the chamber and keeping the inside of the chamber clean.

### BRIEF DESCRIPTION OF THE DRAWINGS

FIG. 1 shows a cross-sectional view of a plasma etching device according to an embodiment.

FIG. 2 shows a top plan view showing a first antenna and a second antenna for the plasma etching device of FIG. 1.

FIG. 3 is a flowchart showing an operating method for a plasma etching device according to an embodiment.

FIG. 4 illustrates a plasma etching device having a chamber that is coated with an insulating layer according to an embodiment.

FIG. 5 illustrates the plasma etching device having etching by-products attached to an inside of the chamber as a result of an object being etched in the plasma etching device according to an embodiment.

FIG. 6 illustrates the plasma etching device after removal of an insulating layer to clean the inside of the chamber in the plasma etching device according to an embodiment.

### DETAILED DESCRIPTION

The present disclosure describes specific embodiments with reference to the accompanying drawings, in which example embodiments of the disclosure are shown and in which like reference numerals refer to like or similar components. As those skilled in the art will realize, the described embodiments may be modified in various different ways, all without departing from the spirit or scope of the present disclosure. To clearly describe specific embodiments of the present disclosure, descriptions of features, components, or parts that are irrelevant to the description may be omitted.

The accompanying drawings are provided only in order to allow embodiments disclosed in the present specification to be easily understood and are not to be interpreted as limiting the spirit disclosed in the present specification, and the scope of the present disclosure is intended to include all modifications, equivalents, and substitutions without departing from the scope and spirit of the claims.

Sizes and thicknesses of components shown in the accompanying drawings may be altered for ease of illustration or description and for better understanding. Accordingly, the present disclosure is not limited to the illustrated sizes and thicknesses. For example, in the drawings, the thicknesses of layers, films, panels, regions, etc., may be exaggerated for clarity or for better understanding and ease of description.

An element such as a layer, film, region, or substrate referred to herein as being “on” another element may be directly on the other element or intervening elements may also be present. In contrast, an element is referred to as being “directly on” another element means that no intervening elements are present. Further, the specification uses words such as “on” or “above” in a relative sense and does not necessarily indicate positions based on a gravitational direction.

Unless explicitly stated to the contrary, the word “comprise” and variations such as “comprises” or “comprising” should be understood to imply the inclusion of stated elements but not the exclusion of any other elements.

Throughout the specification, the phrase “in a plan view” means object portion is viewed from above a major surface, and the phrase “in a cross-sectional view” means an object portion is viewed after a cross-section taken by cutting the object.

Throughout the specification, “connected” does not mean only that two or more components are only directly connected, but two or more components may be connected indirectly through other components, physically connected as well as being electrically connected, or that two or more components are referred to by different names depending on the location or function but are integral.

Hereinafter, various embodiments and variations will be described in detail with reference to drawings.

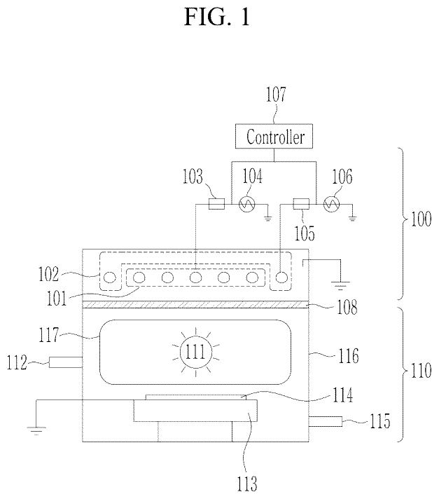

FIG. 1 shows a cross-sectional view of a plasma etching device according to an embodiment.

Referring to FIG. 1, the plasma etching device according to an embodiment of the present disclosure may include an antenna portion 100 and a chamber portion 110.

According to an embodiment, the antenna portion 100 may include a first antenna 101, a second antenna 102, a first matcher 103, a high-frequency power source 104, a second matcher 105, a low-frequency power source 106, a controller 107, and an insulating plate 108. In some embodiments, the plasma etching device may omit at least one of the above-described components or may additionally include other components.

According to an embodiment, the controller 107 may be electrically connected to the high-frequency power source 104 and the low-frequency power source 106. According to an embodiment, the controller 107 may control turning on/off the high-frequency power source 104 and/or the low-frequency power source 106. The controller 107 may control an electric power applied to the first antenna 101 and/or the second antenna 102 by controlling the high-frequency power source 104 and/or the low-frequency power source 106. For example, the controller 107 may control a power applied to the first antenna 101 by controlling the high-frequency power source 104. In addition, for example, the controller 107 may control a power applied to the second antenna 102 by controlling the low-frequency power source 106. According to various embodiments, the controller 107 may control operation of the plasma etching device by controlling at least one other component of the plasma etching device connected to the controller 107.

According to an embodiment, the first antenna 101 may be positioned above a chamber 116. Specifically, the first antenna 101 may be positioned on a central portion of the chamber 116 with an insulating plate 108 between the first antenna 101 and the chamber 116. According to an embodiment, the first antenna 101, which may be an inductively coupled plasma antenna, may be formed of a conductor wound in a spiral shape along a clockwise or counterclockwise direction. That is, the first antenna 101 may include a coil wound in a spiral shape along a clockwise or counterclockwise direction.

According to an embodiment, the second antenna 102 may be positioned above the chamber 116. Specifically, the second antenna 102 may be positioned along at least a portion of an outer edge of an upper portion of the chamber 116 with the insulating plate 108 extending between the second antenna 102 and the chamber 116. Additionally, the second antenna 102 may be positioned in or adjacent to an outer region of the first antenna 101. Specifically, the second antenna 102 may extend along at least a portion of a circumference or perimeter of the first antenna 101. The second antenna 102 may thus be driven to generate an induced electric or electromagnetic field inside the chamber 116 and extending to an outer region of the interior of chamber 116 when the second antenna 102 extends along at least a portion of an outer upper region of the chamber 116.

According to an embodiment, the first antenna 101 may be connected to the high-frequency power source 104 for supplying a radio-frequency (RF) power. More specifically, an end portion of the first antenna 101 at a center of a spiral of the first antenna 101 may be connected to the high-frequency power source 104. The high-frequency power source 104 may, for example, apply an RF high-frequency power having a frequency of 13.56 MHz to the first antenna 101. When the controller 107 turns on the high-frequency power source 104, the RF power of the high-frequency power source 104 may be supplied to and radiated by the first antenna 101.

According to an embodiment, the first matcher 103 may be installed between the first antenna 101 and the high-frequency power source 104. The first matcher 103 may be positioned between the first antenna 101 and the high-frequency power source 104 to match the impedances of the first antenna 101 and the high-frequency power source 104.

According to an embodiment, the second antenna 102 may be connected to the low-frequency power source 106 and may be driven to supply an RF power to the interior of the chamber 116. More specifically, one of the end portions of the second antenna 102 positioned at an edge of the second antenna 102 may be connected to the low-frequency power source 106. For example, the low-frequency power source 106 may apply an RF low-frequency power having a frequency of 1 MHz or less to the second antenna 102. When the controller 107 turns on the low-frequency power source 106, the RF power of the low-frequency power source 106 may be supplied and radiated by to the second antenna 102.

According to an embodiment, the second matcher 105 may be positioned between the second antenna 102 and the low-frequency power source 106. The second matcher 105 may be positioned between the second antenna 102 and the low-frequency power source 106 to match the impedances of the second antenna 102 and the low-frequency power source 106.

According to an embodiment, the insulating plate 108 may separate the first antenna 101 and the second antenna 102 from the chamber 116. The insulating plate 108 may reduce capacitive coupling between the first antenna 101 and the second antenna 102 and a plasma 111 in the chamber 116, to help transfer energy from the high-frequency power source 104 and/or the low-frequency power source 106 to the plasma 111 by inductive coupling.

According to an embodiment, the chamber portion 110 may include a gas inlet 112, a fluid outlet 115, and the chamber 116.

Inside the chamber 116, a plasma reaction chamber 117 and a substrate support member 113 for positioning a substrate 114, etc. thereon may be positioned. For example, the substrate support member 113 may be an electrostatic chuck (ESC) that supports the substrate 114 and uses an electrostatic force to adsorb and hold the substrate 114. Alternatively, the substrate support member 113 may include a vacuum chuck for affixing the substrate 114 using a mechanical clamping method or adsorbing and supporting the substrate 114 by vacuum pressure.

The gas inlet 112 supplies a reaction gas to the plasma reaction chamber 117, and the fluid outlet 115 is used to maintain the plasma reaction chamber 117 of the chamber 116 in a vacuum and to discharge from the chamber 116 the reaction gas when a reaction, e.g., etching, is completed.

According to an embodiment, an etching process using plasma may be performed inside the chamber 116. Specifically, inside the chamber 116, an etching gas (e.g., BCl₃, H₂, or Ar) may be supplied through the gas inlet 112 where high-frequency power may transform the etching gas into a plasma state, which allows the etching process of the substrate 114 to proceed. Additionally, a cleaning process using plasma may be performed inside the chamber 116. Specifically, a cleaning gas (e.g., NF₃, or O₂) may be supplied through the gas inlet 112 into the chamber 116 where low-frequency power transforms the cleaning gas into a plasma state, which allows the cleaning process to proceed after the etching process.

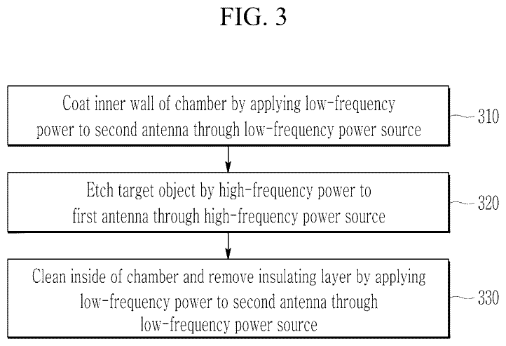

Details of how the etching process and the cleaning process are performed in the plasma etching device according to an embodiment of the present disclosure are further described below with reference to FIGS. 3 to 6.

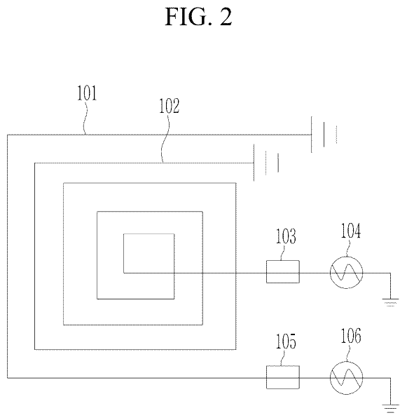

FIG. 2 illustrates a top plan view an embodiment of the first antenna 101 and the second antenna 102 of FIG. 1.

Referring to FIG. 2, the first antenna 101 has a planar shape including a spiral formed with straight conductive sections, which may correspond to a box-shaped interior of the plasma reaction chamber 117, but the first antenna 101 may have a planar shape that is symmetrical in all directions. According to an embodiment, the first antenna 101 is shaped to generate an induced electric field of uniform intensity throughout an internal space of the plasma reaction chamber 117.

As shown in FIG. 2, the first antenna 101 may have a quadrangular spiral coil planar shape when viewed from the top of the chamber 116. However, the present disclosure is not limited thereto, and the planar shape of the first antenna 101 may be provided in various planar shapes depending on planar structures of the chamber 116, the plasma reaction chamber 117, the substrate support member 113, and the substrate 114.

The first antenna 101 may have a plurality of curved portions and have a spirally wound shape. According to an embodiment, a curved portion of the first antenna 101 may be bent at a predetermined angle (e.g., 90 degrees). For example, the first antenna 101 may be bent at a predetermined angle in a corner region. However, the present disclosure is not limited thereto. For example, corners of the first antenna 101 may be curved into a round shape with a predetermined radius of curvature.

Sections in the spiral of the first antenna 101 may be parallel to each other and spaced at a predetermined distance to maintain an appropriate distance within a range that avoids current interference.

According to an embodiment, the first antenna 101 may be connected to the high-frequency power source 104 through the first matcher 103. The first matcher 103 may be positioned between the first antenna 101 and the high-frequency power source 104 to match impedance of the first antenna 101.

A first end portion of the first antenna 101 positioned at a center of a spiral of the first antenna 101 may be connected to the high-frequency power source 104. A second end portion of the first antenna 101 may be grounded.

According to an embodiment, the high-frequency power source 104 may supply RF power. For example, when the high-frequency power source 104 is turned on, the high-frequency power source 104 may apply RF high-frequency power having a frequency of about 13.56 MHz to the first antenna 101. In this case, the RF power of the high-frequency power source 104 may be dispersed and supplied to the first antenna 101.

As shown in FIG. 2, the second antenna 102 may extend outside and along at least a portion of a circumference or perimeter of the first antenna 101 in an outer region of the first antenna 101. Specifically, when the first antenna 101 has a quadrangular spiral coil planar shape, the second antenna 102 may extend along at least one side of the first antenna 101. For example, when the first antenna 101 has a quadrangular spiral coil planar shape, the second antenna 102 may extend along three sides of the first antenna 101.

According to an embodiment, the second antenna 102 may have a plurality of corners or curved portions. According to an embodiment, a curved portion of the second antenna 102 may be bent at a predetermined angle (e.g., 90 degrees). For example, the second antenna 102 may be bent at a predetermined angle adjacent to a corner region of the first antenna 101. However, the present disclosure is not limited thereto, and the second antenna 102 may be curved into a round shape or arc with a predetermined radius.

According to an embodiment, the second antenna 102 may be connected to the low-frequency power source 106 through the second matcher 105. The second matcher 105 may be positioned between the second antenna 102 and the low-frequency power source 106 to match the low-frequency power source 106 to the impedance of the second antenna 102. The low-frequency power source 106 may specifically be connected to a first end of the second antenna 102. A second end of the second antenna 102 may be grounded.

According to an embodiment, the low-frequency power source 106 may supply RF power. For example, when the low-frequency power source 106 is turned on, the low-frequency power source 106 may apply an RF low-frequency power of about 1 MHz or less to the second antenna 102. In this case, the RF power of the low-frequency power source 106 may be dispersed and supplied to the second antenna 102.

FIG. 3 is a flowchart showing an operating method for a plasma etching device according to an embodiment.

The operations shown in FIG. 3 may be performed sequentially but are not necessarily performed sequentially. For example, the order of the operations may be changed, and at least two operations may be performed in parallel. In some embodiments, some of the operations shown in FIG. 3 may be omitted, some operations may be combined, the order of some operations may be changed, or other operations may be added.

Referring to FIG. 3, in an operation 310, a plasma etching device may coat an inside of a chamber with an insulating layer by applying low-frequency power to a second antenna (e.g., the second antenna 102 in FIG. 1) through a low-frequency power source (e.g., the low-frequency power source 106 in FIG. 1) while the plasma etching device contains a gas suitable for forming the insulating layer.

According to an embodiment, the plasma etching device may control the low-frequency power source 106 to be in an on state during the operation 310. For example, the plasma etching device may switch the low-frequency power source 106 from the off state to the on state. Alternatively, for example, the plasma etching device may continuously maintain the low-frequency power source 106 in the on state. In this case, the high-frequency power source (e.g., the high-frequency power source 104 in FIG. 1) may be in the off state or the on state.

The plasma etching device may apply low-frequency power to the second antenna 102 through the low-frequency power source 106 to generate plasma discharge inside a chamber (e.g., the chamber 116 in FIG. 1). For example, the plasma etching device, i.e., the low-frequency power source 106, may apply an RF low-frequency power having a frequency of about 1 MHz or less to the second antenna 102 positioned on an outer region of the chamber 116. However, the present disclosure is not limited thereto, and the plasma etching device may change the RF power applied to the second antenna 102 in various ways.

The plasma etching device may generate a plasma discharge inside the chamber 116, and then coat an inside of the chamber 116 with an insulating layer. For example, the insulating layer including a nitride layer or an oxide layer may be created using a gas mixture of SiH₄ and N₂O.

As described above, according to an embodiment of the present disclosure, an insulating layer may be efficiently coated on an outer region inside the chamber by applying power to the second antenna positioned at an edge region of an upper portion of the chamber. In addition, as described above, the inside of the chamber may be coated with the insulating layer by applying low-frequency power rather than high-frequency power, improving power efficiency.

According to an embodiment, in an operation 320, the plasma etching device (e.g., through the high-frequency power source 104 in FIG. 1) may apply high-frequency power to a first antenna (e.g., the first antenna 101 in FIG. 1) while an appropriate etch gas is present in the chamber to etch a target object to be etched. For example, the target object to be etched may include a copper layer included in or on a substrate (e.g., the substrate 114 in FIG. 1). More specifically, the target object may correspond to a copper layer to be etched on the substrate 114 to form a circuit or device including a wire, an electrode, etc.

According to an embodiment, the plasma etching device may control the high-frequency power source 104 to be turned on. For example, the plasma etching device may switch the high-frequency power source 104 from the off state to the on state. Alternatively, for example, the plasma etching device may continuously maintain the high-frequency power source 104 in the on state. In this case, the low-frequency power source 106 may be in the off state or the on state.

According to an embodiment, the plasma etching device (e.g., through the high-frequency power source 104) may apply RF high-frequency power to the first antenna 101 positioned on a center of the chamber 116. For example, the plasma etching device may operate the high-frequency power source 104 to apply RF high-frequency power having a frequency of about 13.56 MHz to the first antenna 101. However, the present disclosure is not limited thereto, and the plasma etching device may change the RF power applied to the first antenna 101 in various ways.

According to an embodiment, applying the RF high-frequency power to the first antenna 101 forms an oscillating magnetic field around the first antenna 101. The magnitude and direction of the magnetic field oscillate at the frequency of the RF high-frequency power and generate an induced electric field inside the chamber 116, and oscillation of the induced electric field heats electrons to generate an inductively coupled plasma. In the plasma 111 state, electrons may collide with surrounding neutral gas particles to generate ions and radicals, and the generated ions and radicals may etch the substrate 114.

According to an embodiment, the plasma etching device may etch the etching target object of the substrate 114 using an inert gas. For example, the inert gas may include at least one of BCl₃, H₂, or Ar. According to an embodiment, the target object may be etched, and etching by-products may attach to the inside of the chamber. For example, etching by-products from the copper layer may be deposited (or attached) on the insulating layer coated inside the chamber.

As described above, according to an embodiment of the present disclosure, an etching rate may be improved by etching the target object to be etched using the first antenna connected to the high-frequency power source.

According to an embodiment, in an operation 330, the plasma etching device (e.g., through the low-frequency power source 106) may apply low-frequency power to the second antenna 102 to clean the inside of the chamber 116 and remove the insulating layer. Specifically, the plasma etching device may operate the low-frequency power source 106 to apply RF low-frequency power having a frequency of about 1 MHz or less to the second antenna 102 positioned on an outer region of the chamber 116.

According to an embodiment, during a cleaning operation, the plasma etching device may control the low-frequency power source 106 to be turned on. For example, the plasma etching device may convert the low-frequency power source 106 from the off state to the on state. Alternatively, for example, the plasma etching device may maintain the low-frequency power source 106 in the on state. In this case, the plasma etching device may control the high-frequency power source 104 to be turned off. For example, the plasma etching device may switch the high-frequency power source 104 from the on state to the off state. Alternatively, for example, the plasma etching device may maintain the high-frequency power source 104 in the off state. That is, the cleaning operation inside the chamber 116 may be performed with the low-frequency power source 106 turned on and the high-frequency power source 104 turned off.

According to an embodiment, the plasma etching device may clean the inside of the chamber 116 using a supplied cleaning gas. For example, the cleaning gas may include at least one of NF₃ or O₂, but this is an example, and the present disclosure is not limited thereto. The plasma etching device may apply low-frequency power to the second antenna 102 to convert the introduced cleaning gas into a radical form. For example, if the cleaning gas is NF₃, cleaning gas may be ionized into a plasma state by being ionized with radicals such as NF₂, NF, F, N, etc. The radicals of the cleaning gas inside the chamber 116 may react with the insulating layer and/or the by-products of etching target object, turning the insulating film and/or the by-products of etching the target object into a gaseous state, and the gaseous by-products are exhausted from the chamber 116, cleaning of the inside of the chamber 116. That is, the plasma etching device may clean the inside of the chamber 116 so as to remove the insulating layer. Accordingly, the plasma etching device may remove the etching by-products attached to the insulating layer while removing the insulating layer.

The plasma etching device according to an embodiment of the present disclosure may repeatedly perform the above-described operations 310, 320, and 33. As described above, according to an embodiment, the plasma etching device may perform the above-described operations repeatedly to perform etching processes and keep the inside of the chamber clean, thereby improving a facility operation rate and minimizing errors due to defects.

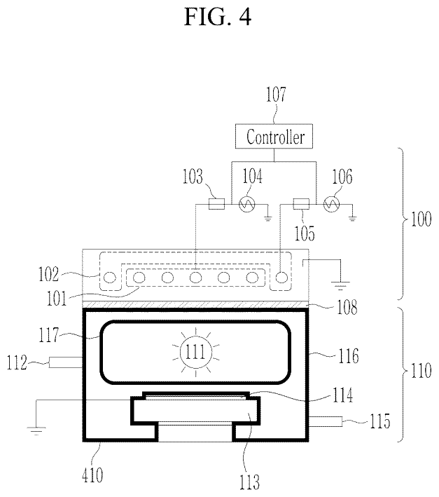

FIGS. 4 to 6 show cross-sections of a plasma etching device during different stages of conditioning, etching, and cleaning operations. The plasma etching device according to the embodiments shown in FIGS. 4 to 6 has many of the same components as the plasma etching device according to the embodiment shown in FIG. 1, and redundant description of the components already described above may be simplified or omitted in the following. The same reference numerals are used for components that are the same as or similar to those described above.

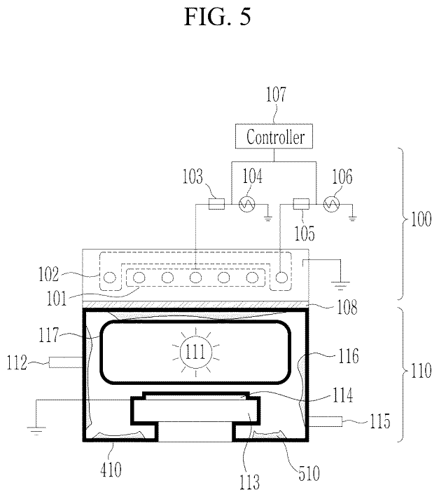

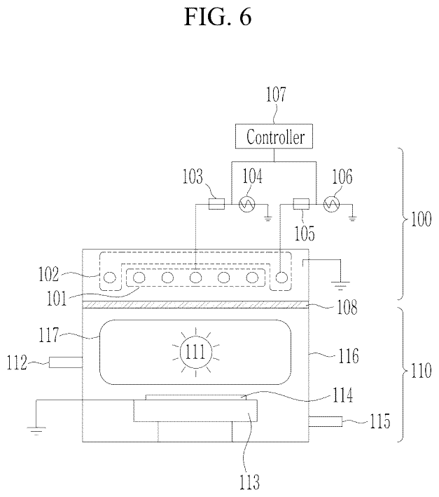

FIG. 4 illustrates a plasma etching device with an insulating layer coating a chamber in the plasma etching device according to an embodiment. FIG. 5 illustrates etching by-products that may attach to the insides of a chamber when a target object to be etched is etched in a plasma etching device according to an embodiment. FIG. 6 illustrates cleaning an inside of a chamber in a plasma etching device according to an embodiment by removing the insulating layer.

Referring to FIG. 4, according to an embodiment, a reaction gas required to create an insulating layer 410 may be injected into the chamber 116 through the gas injection hole 112. For example, the reaction gas may include a mixture of SiH₄ and N₂O.

According to an embodiment, the plasma etching device may apply low-frequency power to the second antenna 102 through the low-frequency power source 106 to generate a plasma discharge inside the chamber 116. Specifically, the plasma etching device may use the low-frequency power source 106 to apply an RF low-frequency power having a frequency of about 1 MHz or less to the second antenna 102 positioned in or on the chamber 116.

According to an embodiment, the plasma etching device may generate plasma discharge inside the chamber 116 that then causes coating an inside of the chamber 116 with the insulating layer 410. For example, the plasma etching device may coat the inside of the chamber 116 with a nitride layer or an oxide layer using the mixture of SiH₄ and N₂O gas.

In this specification, coating the insulating layer 410 on the inside of the chamber 116 may indicate that the insulating layer 410 is coated on components exposed to plasma inside the chamber 116 or surfaces of an inner wall of the chamber 116. For example, the insulating layer 410 may be coated on surfaces of the plasma reaction chamber 117, the substrate 114, and the substrate support member 113 for positioning the substrate 114, which may be inside the chamber 116. In some embodiments, in addition to the above-described components, the insulating layer 410 may coat surfaces of other components inside the chamber 116.

As described above, according to an embodiment, power efficiency may be improved by applying low-frequency electric power rather than high-frequency electric power during the coating operation.

In addition, as described above, according to an embodiment of the present disclosure, the second antenna being in a region above an edge of the chamber may cause an insulation layer to be uniformly coated not only in a center region of the chamber but also in an edge region of the chamber. That is, the second antenna being in a region above an edge of the chamber may cause the insulation layer to be uniformly coated on all interior surfaces of the chamber 116, not just surfaces near the center of the chamber 116.

Referring to FIG. 5, the plasma etching device may use the high-frequency power source 104 to apply high-frequency power to the first antenna 101 to etch the etching target object, e.g., the substrate 114. For example, the plasma etching device may operate the high-frequency power source 104 to apply RF high-frequency power having a frequency of about 13.56 MHz to the first antenna 101. However, the present disclosure is not limited thereto, and the plasma etching device may change the RF power applied to the first antenna 101 in various ways.

According to an embodiment, when an RF power from the high-frequency power source 104 is applied to the first antenna 101, a current flowing along the first antenna 101 generates an oscillating magnetic field in a space inside the plasma reaction chamber 117. An induced electric field is generated due to changes in a magnetic field over time, and a reaction gas supplied to the plasma reaction chamber 117 through the gas inlet 112 obtains from the induced electric field sufficient energy for ionization that generates plasma. According to an embodiment, the reaction gas supplied to the plasma reaction chamber 117 through the gas inlet 112 may include an inert gas. For example, the inert gas corresponding to the neutral gas particles may include at least one of BCl₃, H₂, or Ar in the etching gas.

According to an embodiment, the plasma etching device may generate an induced electromagnetic field in the chamber 116 using the first antenna 101. The plasma etching device may perform an etching process on an etching object, e.g., substrate 114, using the plasma 111 that the induced electromagnetic field generates. For example, the target object to be etched may include a copper layer included in the substrate 114.

According to an embodiment, an etching by-product 510 may be generated by an etching reaction of the target object to be etched using the plasma 111. For example, when the target object to be etched is a copper layer, the etching by-product 510 may include CuClx generated by a radical reaction between copper and chlorine. Alternatively, for example, the etching by-product 510 may include CuH generated by a radical reaction between copper and hydrogen.

According to an embodiment, the etching by-product 510 may adhere to components inside the chamber 116 or to the inner wall of the chamber 116. Specifically, the etching by-product 510 may attach to the insulating layer 410 coated on the surface of components or the inner wall of the chamber 116. According to various embodiments, the amount of etching by-product 510 attached to at least one component inside the chamber 116 and the inner wall of the chamber 116 after an etching process may vary.

Referring to FIG. 6, cleaning gas may be supplied through the gas inlet 112 into the chamber 116. For example, the cleaning gas may include at least one of NF₃ or O₂, but this is an example, and the present disclosure is not limited thereto.

According to an embodiment, the plasma etching device may clean the inside of the chamber 116 using the supplied cleaning gas. The plasma etching device may apply low-frequency power to the second antenna 102 to convert particles of the introduced cleaning gas into a radical form. For example, if the cleaning gas is molecular NF₃, cleaning gas may be ionized into a plasma state and to create radicals such as NF₂, NF, F, N, etc. The radicals of the cleaning gas may react with the insulating layer 410 and/or the etching by-products 510 inside the chamber 116 to turn the insulating layer 410 and/or the etching by-products 510 into a gaseous state or gaseous molecules. The gaseous by-products may be exhausted through the fluid outlet 115, and cleaning inside the chamber 116 may proceed. That is, the plasma etching device may remove the insulating layer 410 to clean the inside of the chamber 116. Accordingly, the plasma etching device may remove the etching by-product 510 attached to the insulating layer 410 while removing the insulating layer 410. Specifically, as cleaning inside the chamber 116 progresses, the insulating layer 410 may be peeled off, and thus the etching by-product 510 attached to the insulating layer 410 may also be removed.

As described above, according to an embodiment of the present disclosure, not only the center of the chamber but also the edge region of the chamber may be cleaned by positioning the second antenna in the region above the edge of the chamber.

In addition, according to an embodiment of the present disclosure, the plasma etching device may include both the first antenna connected to the high-frequency power source and the second antenna connected to the low-frequency power source, to maximize process efficiency by using the second antenna for a process where low-frequency power is sufficient and the first antenna for a process that requires high-frequency power.

While this disclosure has been described in connection with what is presently considered to be practical embodiments, the disclosure is not limited to the disclosed embodiments, but, to the contrary, this disclosure is intended to cover various modifications and equivalent dispositions included within the spirit and scope of the appended claims.

### DESCRIPTION OF SYMBOLS

100: antenna portion
101: first antenna
102: second antenna
103: first matcher
104: high-frequency power source
105: second matcher
106: low-frequency power source
107: controller
108: insulating plate
110: chamber portion
111: plasma
112: gas inlet
113: substrate support member
114: substrate
115: fluid outlet
116: chamber
117: plasma reaction chamber
410: insulating layer
510: etching by-product

What is claimed is:

1. A plasma etching device comprising:
a chamber in which an etching process using plasma is performed, an inside of which is coated with an insulating layer before the etching process, the insulating layer being removable after the etching process;
a first antenna connected to a high-frequency power source and positioned on the chamber;
a second antenna connected to a low-frequency power source and positioned around at least a portion of a perimeter of the first antenna; and
a controller electrically connected to the high-frequency power source and the low-frequency power source to control the high-frequency power source and the low-frequency power source.

2. The plasma etching device of claim 1, wherein the controller is configured to apply low-frequency power to the second antenna through the low-frequency power source to generate plasma discharge inside the chamber to coat the insulating layer on the inside of the chamber.

3. The plasma etching device of claim 1, wherein the insulating layer is a nitride layer or an oxide layer created using a mixed gas of SiH₄ and N₂O.

4. The plasma etching device of claim 1, wherein the controller is configured to apply high-frequency power to the first antenna through the high-frequency power source to etch a target object to be etched.

5. The plasma etching device of claim 1, wherein the controller is configured to apply low-frequency power to the second antenna through the low-frequency power source to clean an inside of the chamber and remove the insulating layer.

6. The plasma etching device of claim 1, wherein low-frequency power applied to the first antenna through the low-frequency power source has a frequency of 1 MHz or less.

7. The plasma etching device of claim 1, wherein the controller is configured to control the high-frequency power source to be turned off when low-frequency power is applied to the second antenna to remove the insulating layer.

8. The plasma etching device of claim 1, wherein the first antenna is formed of a conductor wound in a spiral.

9. The plasma etching device of claim 7, wherein the first antenna has a quadrangular spiral coil shape.

10. The plasma etching device of claim 1, wherein the second antenna extends along at least a portion of an outer edge of an upper portion of the chamber.

11. The plasma etching device of claim 1, further comprising an insulating plate positioned below the first antenna and the second antenna and above the chamber.

12. An operating method for a plasma etching device including a chamber where an etching process using plasma is performed, a first antenna connected to a high-frequency power source and positioned on the chamber, a second antenna connected to a low-frequency power source and positioned at an outer edge of the first antenna; and a controller electrically connected to the high-frequency power source and the low-frequency power source, the operating method comprising:
coating an inside of the chamber with an insulating layer by applying low-frequency power to the second antenna;
etching a target object to be etched by applying high-frequency power to the first antenna; and
cleaning the inside of the chamber and removing the insulating layer by applying the low-frequency power to the second antenna.

13. The operating method of claim 12, wherein the coating of the inside includes applying the low-frequency power to the second antenna to generate plasma discharge inside the chamber, the plasma discharge then coating the insulating layer on the inside of the chamber.

14. The operating method of claim 12, wherein the insulating layer includes a nitride layer or an oxide layer created using a mixed gas of SiH₄ and N₂O.

15. The operating method of claim 12, wherein a frequency of the low-frequency power is less than 1 MHz.

16. The operating method of claim 12, wherein the etching of the target object includes etching the target object using an inert gas.

17. The operating method of claim 16, wherein the inert gas includes at least one of BCl₃, H₂, and Ar.

18. The operating method of claim 12, wherein the removing of the insulating layer includes cleaning the inside of the chamber and removing the insulating layer while the high-frequency power source is turned off.

19. The operating method of claim 12, wherein the removing of the insulating layer includes removing an etching by-product attached to the insulating layer.

20. The operating method of claim 12, wherein the removing the insulating layer includes removing the insulating layer using at least one of NF₃ or O₂.
